(19) United States
(12) Patent Application Publication
(10) Pub. No.: US 2010/0052084 A1
(43) Pub. Date: Mar. 4, 2010

(54) IMAGE SENSOR AND MANUFACTURING METHOD THEREOF

(76) Inventor: TAEK SEUNG YANG, Gyeonggi-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/536,666

(22) Filed: Aug. 6, 2009

(30) Foreign Application Priority Data
Aug. 28, 2008 (KR) 10-2008-0084698

(51) Int. Cl. H01L 31/0232; H01L 31/02

(52) U.S. Cl. 257/432; 438/70; 438/59; 257/E31.127; 257/E31.11

(57) ABSTRACT

Disclosed are an image sensor employing an annealing process and a manufacturing method thereof. According to the method, in one embodiment, a transistor structure is formed over a semiconductor substrate, a metal interconnection layer is formed over the transistor structure, a protective layer is formed over the metal interconnection layer, a nitride layer is formed over the protective layer, and the semiconductor substrate formed with the nitride layer is subject to a high pressure annealing process.

This application claims the benefit under 35 U.S.C. §119 to Korean Patent Application No. 10-2008-0084698, filed on Aug. 28, 2008, which is hereby incorporated by reference in its entirety.

### BACKGROUND

In general, an image sensor is a semiconductor device that converts an optical image into an electrical signal, and is typically classified into a charge coupled device (CCD) and a complementary metal oxide semiconductor (CMOS) image sensor.

Recently, the CMOS image sensor has been spotlighted as the next generation image sensor.

The CMOS image sensor is manufactured through a CMOS manufacturing technology, so the CMOS image sensor has an advantage of low power consumption. In addition, the CMOS image sensor can be manufactured through a simple manufacturing process where the number of photo process steps is reduced. Further, a control circuit, a signal processing circuit and an analog/digital conversion circuit can be integrated into a CMOS image sensor chip, so that the product can be fabricated in a micro size. Thus, the CMOS image sensor has been extensively applied in various application fields such as digital still cameras and digital video cameras.

According to the conventional CMOS image sensor, an interlayer dielectric layer including undoped silicon glass (USG) is formed over a silicon substrate having a pixel area and a transistor area, a bonding pad is formed over the interlayer dielectric layer, and a protective layer is formed over the interlayer dielectric layer on which the bonding pad is formed.

The CMOS image sensor manufactured in such a manner has many dangling bonds on the surfaces of a gate insulating layer and the silicon substrate. Such dangling bonds may degrade the performance of the image sensor.

In particular, when forming an isolation layer on the silicon substrate, many dangling bonds existing on an interface between the isolation layer and the silicon substrate may serve as a dark current source. Further, the dangling bonds generated when forming the gate insulating layer may reduce charge transfer efficiency because they may serve as a trap that captures electrons during transfer of photoelectrons.

Thus, according to the manufacturing process of the CMOS image sensor, an annealing process is performed to remove defects such as dangling bonds and humidity.

The annealing process for the conventional CMOS image sensor is performed for a long time while supplying a mixture of hydrogen gas and nitrogen gas at a normal pressure (1 atm) or at a pressure lower than the normal pressure, so the product yield may be lowered and device characteristics may be degraded.

### BRIEF SUMMARY

The present disclosure provides an image sensor employing an annealing process and a manufacturing method thereof.

A method of manufacturing an image sensor according to an embodiment includes forming a transistor structure over a semiconductor substrate; forming a metal interconnection layer over the transistor structure; forming a protective layer over the metal interconnection layer; forming a nitride layer over the protective layer; and annealing a semiconductor substrate formed with the nitride layer at a high pressure.

A method of manufacturing an image sensor according to another embodiment includes forming a transistor structure over a semiconductor substrate; and annealing the semiconductor substrate formed with the transistor structure at a high pressure.

A method of manufacturing an image sensor according to another embodiment includes forming a transistor structure over a semiconductor substrate; forming a metal interconnection layer over the transistor structure; and annealing the semiconductor substrate formed with the metal interconnection layer at a high pressure.

A method of manufacturing an image sensor according to another embodiment includes forming a gate pattern over a semiconductor substrate; forming an insulating layer over the semiconductor substrate formed with the gate pattern; forming a first metal interconnection and a capacitor electrode over the insulating layer; forming a first interlayer dielectric layer over the insulating layer formed with the first metal interconnection and the capacitor electrode; sequentially forming a first etch stop layer and a first metal layer over the first interlayer dielectric layer; forming a second metal interconnection by patterning the first metal layer; forming a second interlayer dielectric layer over the first interlayer dielectric layer formed with the second metal interconnection; sequentially forming a second etch stop layer and a second metal layer over the second interlayer dielectric layer; forming a third metal interconnection by patterning the second metal layer; forming a third interlayer dielectric layer over the second interlayer dielectric layer formed with the third metal layer; forming a protective layer over the third interlayer dielectric layer; and forming a color filter layer over the protective layer. After the gate pattern is formed, a high pressure annealing process is performed at least one time.

An image sensor according to an embodiment includes a transistor structure over a semiconductor substrate; an insulating layer covering the transistor structure; a metal interconnection layer over the insulating layer; a protective layer over the metal interconnection layer; and a color filter layer over the protective layer, wherein the semiconductor substrate including at least one of the transistor structure, the insulating layer, the metal interconnection layer, and the protective layer is subject to an annealing process under conditions of a pressure of about 7 atm to about 40 atm and a temperature of about 200° C. to about 600° C.

According to certain embodiments, when manufacturing the CMOS image sensor, the annealing process is performed using gas including at least one of hydrogen, heavy hydrogen and tritium at a high pressure, so that the performance of the CMOS image sensor can be improved.

Further, according to an embodiment, after forming the gate pattern, the annealing process can be performed relative to the semiconductor substrate by using the gas including at least one of hydrogen, heavy hydrogen and tritium at the high pressure.

### BRIEF DESCRIPTION OF THE DRAWINGS

FIG. 1 is a cross-sectional view showing a CMOS image sensor according to an embodiment;

FIGS. 2 to 6 are cross-sectional views showing stages where a high pressure annealing process is performed when manufacturing a CMOS image sensor according to an embodiment;

FIG. 7 is a cross-sectional view showing an image sensor according to another embodiment;

FIG. 8 is a cross-sectional view showing a stage where a high pressure hydrogen annealing process is performed for an image sensor according to another embodiment;

FIG. 9 is a cross-sectional view showing a stage where a high pressure hydrogen annealing process is performed for an image sensor according to another embodiment; and

FIG. 10 is a graph showing variation of a dark code in an image sensor depending on process conditions for a high pressure hydrogen annealing process in accordance with embodiments of the present invention.

### DETAILED DESCRIPTION

Hereinafter, a CMOS image sensor and a manufacturing method thereof according to embodiments will be described in detail with reference to accompanying drawings. Those skilled in the art can modify embodiments within the scope of the appended claims and their equivalents.

Hereinafter, described elements can be selectively or alternatively used. The size (dimension) of elements shown in the drawings may be magnified for the purpose of clear explanation and the real size of the elements may be different from the size of elements shown in drawings. In the description of an embodiment, it will be understood that when a layer (or film) is referred to as being ‘on/above/over/upper’ another layer or substrate, it can be directly on another layer or substrate, or intervening layers may also be present. Further, it will be understood that when a layer is referred to as being ‘down/below/under/lower’ another layer, it can be directly under another layer, or one or more intervening layers may also be present. In addition, it will also be understood that when a layer is referred to as being ‘between’ two layers, it can be the only layer between the two layers, or one or more intervening layers may also be present. Thus, the meaning thereof must be determined based on the scope of the embodiment.

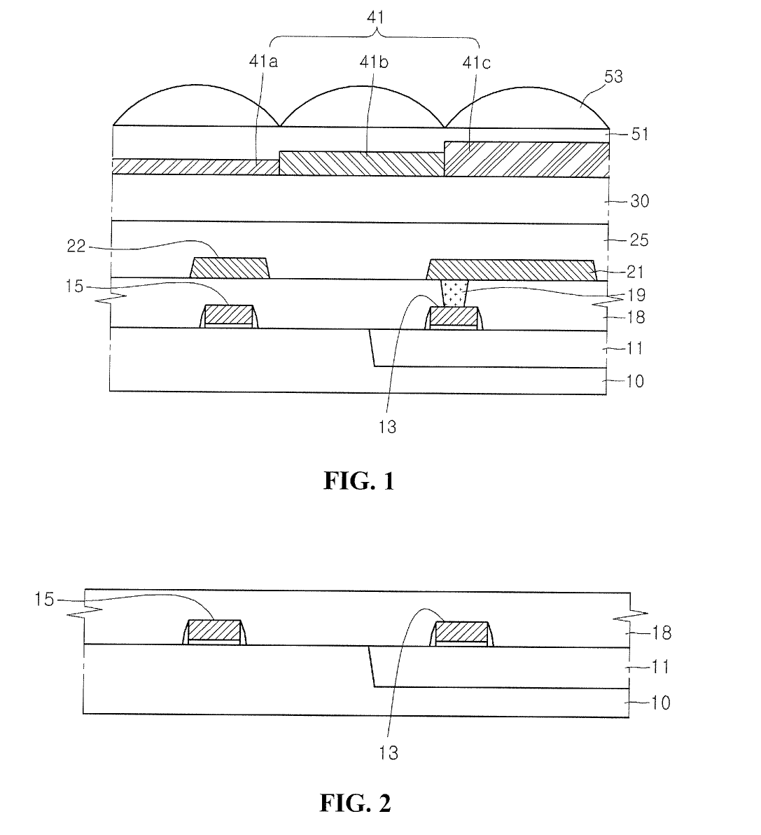

FIG. 1 is a cross-sectional view showing a CMOS image sensor according to an embodiment.

As shown in FIG. 1, a transistor structure 15 and an insulating layer 18 covering the transistor structure 15 are formed over a semiconductor substrate 10.

The transistor structure 15 may include a gate insulating layer, a gate pattern formed over the gate insulating layer, and a gate insulating layer spacer formed at sidewalls of the gate pattern.

Although not shown in FIG. 1, a photodiode area can be formed in or on the semiconductor substrate 10.

When the transistor structure 15 is formed, a capacitor structure 13 can be formed at the same time over an isolation layer 11.

A metal interconnection layer is formed over the semiconductor substrate 10. In an embodiment, a metal interconnection 22 and a capacitor electrode 21, which is connected with the capacitor structure 13 through a via 19, are formed over the insulating layer 18. Then, an interlayer dielectric layer 25 is formed over the insulating layer 18 including the metal interconnection 22 and the capacitor electrode 21.

The metal interconnection layer may include a plurality of interlayer dielectric layers, and metal interconnections and capacitor electrodes, which are formed among the interlayer dielectric layers.

A protective layer 30 is formed over the interlayer dielectric layer 25, and a color filter layer 41 including a blue color filter 41a, a green color filter 41b and a red color filter 41c is formed over the protective layer 30.

A planarization layer 51 can be provided over the color filter layer 41, and a microlens layer 53 for light collection can be formed over the planarization layer 51.

According to the process of forming the CMOS image sensor having a structure as described above, a high pressure annealing process is performed.

The high pressure annealing process is performed to improve properties of a metal gate and device characteristics of the image sensor and to address a problem (e.g., a dark signal) of the image sensor caused by trap charges.

The high pressure hydrogen annealing process is performed under conditions of a pressure of about 7 atm to about 40 atm and a temperature of about 200° C. to about 600° C.

Further, the high pressure hydrogen annealing process uses gas including at least one of hydrogen, heavy hydrogen and tritium.

The high pressure hydrogen annealing process may include at least one of nitrogen, argon and helium.

The high pressure hydrogen annealing process may be performed for about one second to about one hour.

The high pressure annealing process can be applied to various processes (or stages) after the transistor structure is formed in the CMOS image sensor.

For example, in an embodiment, the substrate including the transistor structure may be subject to the high pressure annealing process before forming the insulating layer covering the transistor structure.

In an embodiment, the semiconductor substrate including the insulating layer, which covers the transistor structure, may be subject to the high pressure annealing process.

In an embodiment, after a metal layer is formed to provide a metal interconnection on the semiconductor substrate including the transistor structure and the insulating layer, the metal layer may be subject to the high pressure annealing process.

In an embodiment, after the metal layer is formed and the metal interconnection is formed through a photolithography process, the high pressure annealing process may be performed. In such a case, hydrogen is not supplied during the high pressure annealing process, so the metal interconnection can be prevented from being oxidized or interconnection characteristics can be prevented from being lowered.

In an embodiment, after the interlayer dielectric layer is formed over the entire surface of the semiconductor substrate including the metal interconnection, the interlayer dielectric layer may be subject to the high pressure annealing process.

Further, after an etch stop layer that may be formed over the interlayer dielectric layer, the high pressure annealing process may also be performed.

In yet another embodiment, a pad may be formed over the metal interconnection layer. In such a case, the high pressure annealing process in accordance with an embodiment of the present invention may be performed before or after the pad is formed.

Furthermore, after the protective layer is formed over the pad (or top metal interconnection layer), the subject high pressure annealing process may also be performed.

In certain embodiments, a silicon nitride layer or a silicon oxynitride layer is formed over the protective layer. In such embodiments, the high pressure annealing process may be performed with respect to the silicon nitride or silicon oxynitride layer.

When the high pressure annealing process is performed relative to the entire surface of the silicon nitride layer, hydrogen H included in the silicon nitride layer diffuses to the surface of the semiconductor substrate through out-diffusion so that the hydrogen H is combined with dangling bonds, thereby curing damage.

The entire thickness of the silicon nitride layer may be reduced through the high pressure annealing process.

Here, the high pressure hydrogen annealing process is performed under the conditions of pressure of about 7 atm to about 40 atm and temperature of about 20° C. to about 600° C.

Further, the high pressure hydrogen annealing process uses gas including at least one of hydrogen, heavy hydrogen and tritium.

The high pressure hydrogen annealing process may include at least one of nitrogen, argon and helium.

The high pressure hydrogen annealing process may be performed for about one second to about one hour.

As described above, after the silicon nitride layer is formed over the protective layer 30 of the image sensor, the semiconductor substrate 10 is subject to the high pressure annealing process, so that defects of the substrate can be cured by the hydrogen, and the dangling bonds can be removed to improve the device characteristics. Particularly, dark current can be reduced from the image sensor.

FIGS. 2 to 6 are sectional views showing stages where the high pressure annealing process can be performed in the process of manufacturing the CMOS image sensor according to an embodiment.

As shown in FIG. 2, the isolation layer 11 is formed on the semiconductor substrate 10. In addition, the transistor structure 15 and the capacitor structure 13 can be formed over the semiconductor substrate 10 including the isolation layer 11. The capacitor structure 13 can include the semiconductor substrate 10, the isolation layer 11, and the gate electrode.

The transistor structure 15 and the capacitor structure 13 may include gate patterns made of polysilicon.

Here, according to an embodiment, the semiconductor substrate 10 including the transistor structure 15 and the capacitor structure 13 is subject to the high pressure annealing process.

The high pressure annealing process is performed under the conditions of pressure of about 7 atm to about 40 atm and temperature of about 200° C. to about 600° C.

Further, the high pressure annealing process uses gas including at least one of hydrogen, heavy hydrogen and tritium.

The high pressure annealing process may include at least one of nitrogen, argon and helium.

The high pressure annealing process may be performed for about one second to about one hour.

Further, after an insulating layer 18 is formed over the semiconductor substrate 10 to cover the transistor structure 15 and the capacitor structure 13, the high pressure annealing process may be performed.

The insulating layer 18 may include an oxide layer. For example, the insulating layer 18 may include boron phosphorus silicate glass (BPSG) and the like.

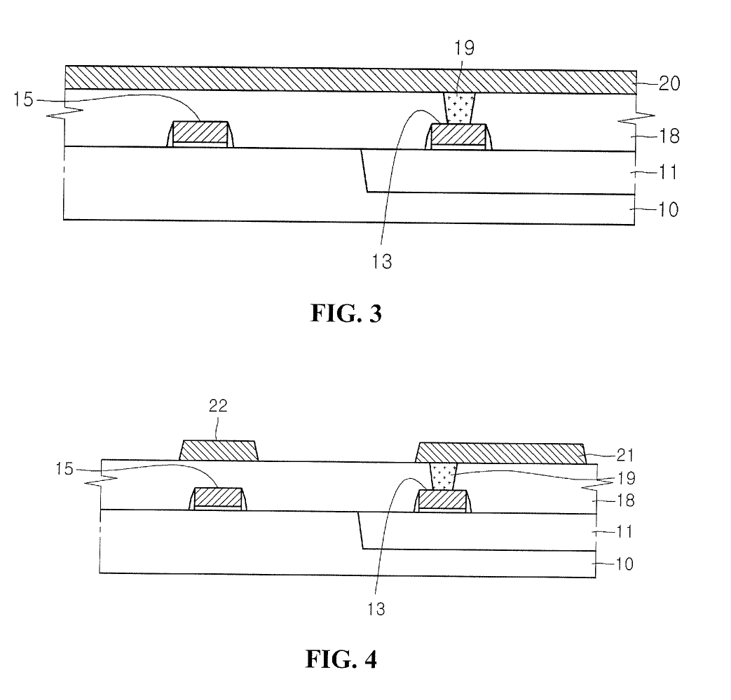

As shown in FIG. 3, a metal layer 20 is formed over the insulating layer 18.

Next, the semiconductor substrate 10 including the metal layer 20 may be subject to the high pressure annealing process according to the embodiment.

The metal layer 20 may have a single layer or a multiple layer using various types of conductive materials including metal, an alloy or silicide. For example, the metal layer 20 may include one selected from the group consisting of aluminum, copper, cobalt and tungsten. The metal layer 20 may be provided at the lower portion thereof with a lower barrier layer, and may be provided at the upper portion thereof with an upper barrier layer. The lower barrier layer and the upper barrier layer may each include Ti/TiN layers.

The insulating layer 18 may be formed with a via or a contact (such as via 19).

As shown in FIG. 4, a metal interconnection 22 and a capacitor electrode 21 are formed by patterning the metal layer 20.

After forming the metal interconnection 22 and the capacitor electrode 21, the high pressure annealing process may be performed.

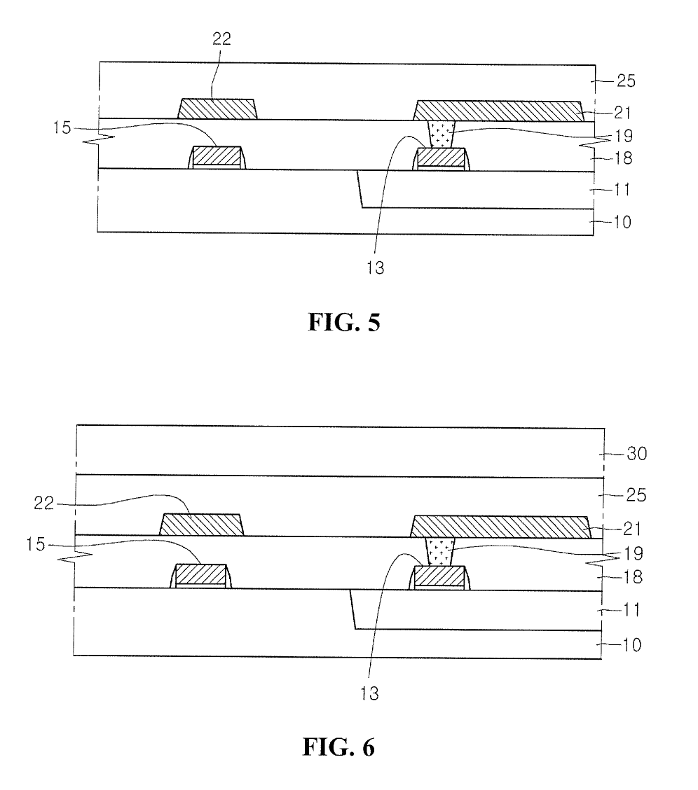

As shown in FIG. 5, after forming the metal interconnection 22, an interlayer dielectric layer 25 is formed.

The interlayer dielectric layer 25 may include an oxide layer. For example, the interlayer dielectric layer 25 may include undoped silicate glass (USG) and the like.

After forming the interlayer dielectric layer 25, the high pressure annealing process may be performed.

The interlayer dielectric layer 25 may include a plurality of layers, and the metal interconnection 22 may be formed between the layers. Further, the high pressure annealing process may be performed before or after forming each metal interconnection layer. In addition, after covering each interconnection layer with an interlayer dielectric layer, the high pressure annealing process may be performed.

For embodiments that include etch stop layers within the interlayer dielectric layers 25, the high pressure annealing process according to the embodiment may be performed on the etch stop layer. The etch stop layer may include a silicon nitride layer or a silicon oxynitride layer.

As shown in FIG. 6, a protective layer 30 is formed over the interlayer dielectric layer 25.

The protective layer 30 may include an oxide layer.

Although not shown in the Figure, a silicon nitride layer or silicon oxynitride layer may be formed over the protective layer 30.

Referring again to FIG. 1, a color filter layer 41 including a blue color filter 41a, a green color filter 41b and a red color filter 41c is formed over the semiconductor substrate 10 including the silicon nitride layer or the silicon oxynitride layer.

Since thicknesses of the blue color filter 41a, the green color filter 41b and the red color filter 41c may be different from each other, a planarization layer 51 may be formed over the color filter layer 41 to planarize the upper surface of the color filter layer 41.

Then, a microlens layer 53 is formed over the planarization layer 51 according to each pixel.

As described above, the high pressure annealing process can be performed at one or more stages after the photodiode and the transistor structure are formed.

According to the image sensor of the embodiment, the high pressure annealing process is performed using gas including at least one of hydrogen, heavy hydrogen, tritium, nitrogen, argon and helium to remove the dangling bonds, so that the device characteristics can be improved. Particularly, the dark current can be reduced from the image sensor.

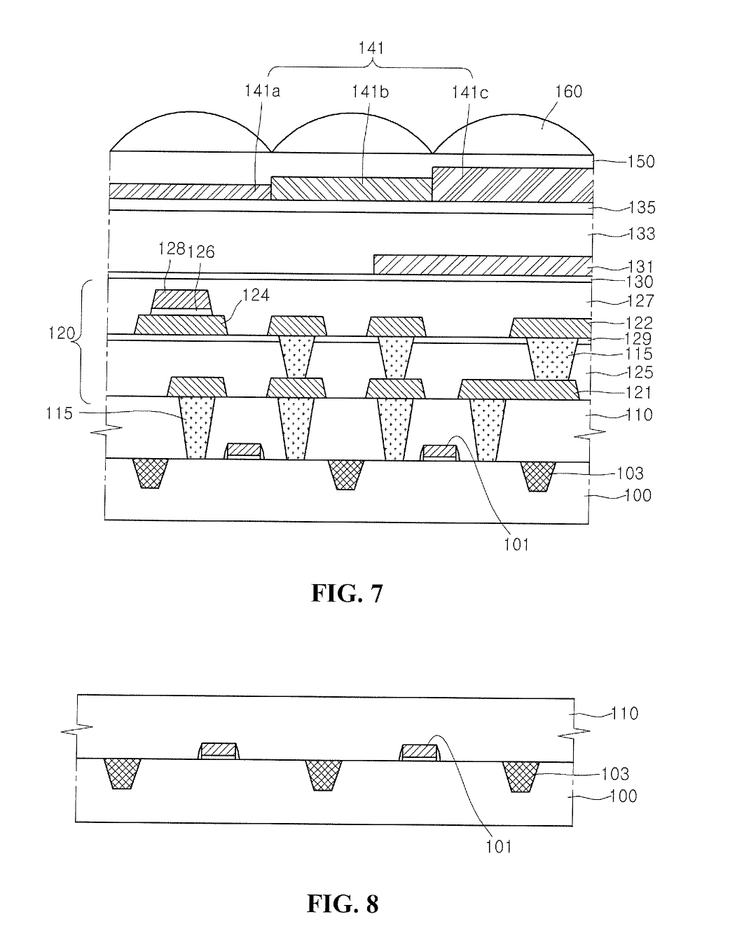

FIG. 7 is a cross-sectional view showing an image sensor according to another embodiment.

As shown in FIG. 7, after a transistor structure 101 and an insulating layer 110 are formed over a semiconductor substrate 100, a metal interconnection layer 120 is formed over the insulating layer 110, and a pad 131, a protective layer 133 and a silicon nitride layer 135 are formed over the metal interconnection layer 120.

The semiconductor substrate 100 may include a single crystalline or multi-crystalline silicon substrate. Further, the semiconductor substrate 100 may be doped with P type impurities or N type impurities.

An isolation layer 103 may be formed in the semiconductor substrate 100 to define an active area and a field area. Further, a circuit and a periphery circuit of a pixel unit may be formed over the active area.

Although not shown in FIG. 7 in detail, a transistor circuit may be formed for the pixel unit in correspondence with each pixel, and may include a transfer transistor connected with a photodiode to convert received photo charges into an electric signal, a reset transistor, a drive transistor and a select transistor.

The metal interconnection layer 120 including metal interconnections 121 and 122, plugs 115 and interlayer dielectric layers 125 and 127 is formed above the semiconductor substrate 100 to connect a power line or a signal line with the circuit. The metal interconnection layer 120 may include the interlayer dielectric layers 125 and 127. Further, the metal interconnection layer 120 may include a capacitor structure and the like. The capacitor structure can include a lower metal pattern 124, a dielectric layer 126 and an upper metal pattern 128.

The metal interconnections 121 and 122 may include various types of conductive materials including metal, an alloy or silicide. For example, the metal interconnections 121 and 122 may include at least one selected from the group consisting of aluminum, copper, cobalt and tungsten. The metal interconnection 121 may include a lower barrier layer, a metal layer and an upper barrier layer. The plugs 115 for connection between the metal interconnections 121 and 122 may be formed in via holes of the interlayer dielectric layers 125 and 127. For example, the plug 115 may include a lower barrier layer and a tungsten layer. The lower barrier layer and the upper barrier layer may each include Ti/TiN layers.

The insulating layer 110 covering the semiconductor substrate 101 may include an oxide layer. In addition, the insulating layer 110 may include the BPSG and the like.

The interlayer dielectric layers 125 and 127 of the metal interconnection layer 120 may include an oxide layer. For example, the interlayer dielectric layers 125 and 127 may include USG and the like.

Each of the interlayer dielectric layers 125 and 127 may include a plurality of interlayer dielectric layers. Further, before the metal layer is formed such that the metal interconnections are formed, etch stop layers 129 and 130 can be formed over the interlayer dielectric layers 125 and 127, respectively. The etch stop layers 129 and 130 may include a silicon nitride layer or a silicon oxynitride layer.

Before or after forming the etch stop layers 129 and 130, the subject high pressure annealing process may be performed.

The protective layer 133 may include an oxide layer.

A silicon nitride layer 135 or a silicon oxynitride layer can be formed over the protective layer 133.

Then, the high pressure annealing process is performed relative to the entire surface of the silicon nitride layer 135. Thus, hydrogen H included in the silicon nitride layer diffuses to the surface of the semiconductor substrate 100 through out-diffusion so that the hydrogen H is combined with dangling bonds, thereby curing the damage.

The entire thickness of the silicon nitride layer 135 may be reduced through the high pressure annealing process.

At this time, the high pressure hydrogen annealing process is performed under the conditions of pressure of about 7 atm to about 40 atm and temperature of about 200° C. to about 600° C.

Further, the high pressure hydrogen annealing process uses gas including at least one of hydrogen, heavy hydrogen and tritium.

The high pressure hydrogen annealing process may include at least one of nitrogen, argon and helium.

The high pressure hydrogen annealing process may be performed for about one second to about one hour.

As described above, after the silicon nitride layer 135 or the silicon oxynitride layer is formed over the protective layer 133 of the image sensor, the semiconductor substrate 100 is annealed at the high pressure, so that defects of the substrate can be cured by the hydrogen, and the dangling bonds can be removed to improve the device characteristics. Particularly, the dark current can be reduced from the image sensor.

Although the high pressure hydrogen annealing process according to embodiments of the present invention is not used to manufacture the structures constituting the image sensor, the high pressure hydrogen annealing process can significantly improve the dark current properties of the image sensor and the properties of the image sensor due to trap charges, so that the product performance, properties and reliability of the image sensor can be significantly improved.

According to an embodiment, the high pressure hydrogen annealing process may be performed after the isolation layer, the transistor structure, the insulating layer, the metal interconnection layer, the pad, the protective layer and the silicon nitride layer are sequentially formed over the silicon substrate.

FIG. 8 is a cross-sectional view showing a stage for a high pressure hydrogen annealing process for the image sensor according to another embodiment.

As shown in FIG. 8, after an isolation layer 103, a transistor structure 101 and an insulating layer 110 are formed over the semiconductor substrate 100, the subject high pressure hydrogen annealing process is performed.

The high pressure hydrogen annealing process is performed under conditions of a pressure of about 7 atm to about 40 atm and a temperature of about 200° C. to about 600° C.

Further, the high pressure hydrogen annealing process uses gas including at least one of hydrogen, heavy hydrogen and tritium.

The high pressure hydrogen annealing process may include at least one of nitrogen, argon and helium.

The high pressure hydrogen annealing process may be performed for about one second to about one hour.

FIG. 9 is a cross-sectional view showing a stage for a high pressure hydrogen annealing process for the image sensor according to further another embodiment.

As shown in FIG. 9, in a state in which the isolation layer 103, the transistor structure 101, the insulating layer 110 and the metal interconnection layer 120 are formed over the semiconductor substrate 100 and then the interlayer dielectric layers 125 and 127 are formed, the high pressure hydrogen annealing process according to the embodiment may be performed.

The metal interconnection layer 120 may include a plurality of interlayer dielectric layers and metal interconnections.

The high pressure hydrogen annealing process may be performed after at least one of the interlayer dielectric layers is formed.

For example, after the first metal interconnection 121 is formed over the insulating layer 110 and the first interlayer dielectric layer 125 is formed over the first metal interconnection 121 to cover the first metal interconnection 121, the high pressure hydrogen annealing process may be performed.

Further, before the pad 131 is formed, the high pressure hydrogen annealing process may be performed.

The high pressure hydrogen annealing process is performed under the conditions of pressure of about 7 atm to about 40 atm and temperature of about 200° C. to about 600° C.

Further, the high pressure hydrogen annealing process uses gas including at least one of hydrogen, heavy hydrogen and tritium.

The high pressure hydrogen annealing process may include at least one of nitrogen, argon and helium.

The high pressure hydrogen annealing process may be performed for about one second to about one hour.

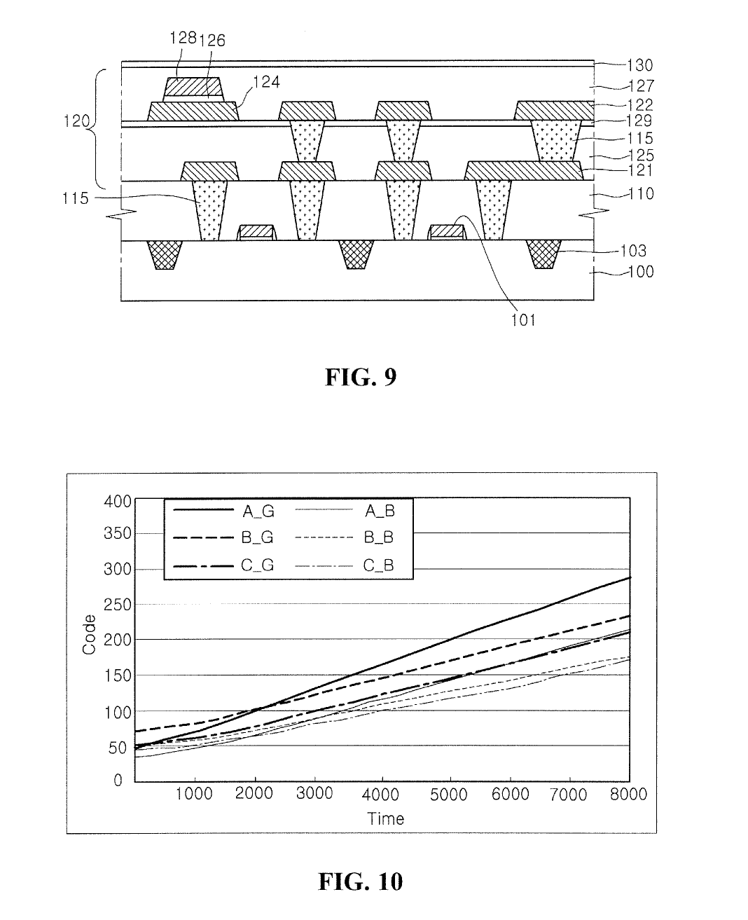

FIG. 10 is a graph showing variation of a dark code (a dark signal) in the image sensor depending on the process conditions for the high pressure hydrogen annealing process.

The result shown in FIG. 10 is obtained by performing the high pressure hydrogen annealing process for 30 minutes at the temperature of about 400° C. after the transistor structure 101, the insulating layer 110, the metal interconnection layers 121 and 122, the pad 131, the protective layer 133 and the silicon nitride layer 135 are sequentially formed, such as shown in FIG. 9.

Referring to FIG. 10, the line A_G represents a dark code of a green signal when the annealing process is performed using hydrogen gas at a pressure of about 1 atm. The line A_B represents a dark code of a blue signal when the annealing process is performed using hydrogen gas at a pressure of about 1 atm.

The line B_G represents a dark code of a green signal when the annealing process is performed using heavy hydrogen gas at a pressure of about 20 atm. The line B_B represents a dark code of a blue signal when the annealing process is performed using heavy hydrogen gas at a pressure of about 20 atm.

The line C_G represents a dark code of a green signal when the annealing process is performed using hydrogen gas at a pressure of about 20 atm. The line C_B represents a dark code of a blue signal when the annealing process is performed using hydrogen gas at a pressure of about 20 atm.

As shown in FIG. 10, when comparing the line A_G and the A_B with the line B_G, the line B_B, the line C_G and the line C_B, the variation of the dark code is reduced in the case of the line B_G, the line B_B, the line C_G and the line C_B.

As compared with the hydrogen annealing process performed at a pressure of about 1 atm, good dark current properties are obtained when the hydrogen annealing process is performed at a pressure of about 20 atm. Further, as compared with the heavy hydrogen annealing process performed at a pressure of about 20 atm, good dark current properties are obtained when the hydrogen annealing process is performed at a pressure of about 20 atm.

Although the high pressure hydrogen annealing process according to embodiments of the present invention is not used to manufacture the structures constituting the image sensor, the high pressure hydrogen annealing process can significantly improve the dark current properties of the image sensor and the properties of the image sensor due to trap charges, so that the performance, properties and reliability of the image sensor can be significantly improved.

The high pressure hydrogen annealing process may be performed after the isolation layer, the transistor structure, the insulating layer, the metal interconnection layer, the pad, the protective layer and the silicon nitride layer are sequentially formed over the silicon substrate.

According to the image sensor of an embodiment, the annealing process is performed using gas including at least one of hydrogen, heavy hydrogen and tritium at the high pressure (above 1 atm at preferably at least about 7 atm), so that the dangling bonds can be removed to improve the device characteristics. Particularly, the dark current can be reduced from the image sensor.

Further, according to the image sensor of an embodiment, after forming an isolation layer on a silicon substrate, the high pressure annealing process is performed at least one time by using gas including at least one of hydrogen, heavy hydrogen and tritium, so that the dangling bonds can be removed from an interface between the isolation layer and the silicon substrate, thereby improving the device characteristics.

Further, according the image sensor of an embodiment, after forming a photodiode and transistors on a silicon substrate and forming a pre-metal dielectric (PMD) layer, the high pressure annealing process is performed at least one time by using gas including at least one of hydrogen, heavy hydrogen and tritium, so that the dark current can be reduced to stabilize the device, thereby improving the device characteristics.

Furthermore, according the image sensor of an embodiment, a plurality of metal interconnection layers are formed over the interlayer dielectric layer. For example, after the interlayer dielectric layer is formed, the metal interconnection layers are formed in or on the interlayer dielectric layer. At this time, when forming the metal interconnection layers, the high pressure annealing process is performed at least one time by using gas including at least one of hydrogen, heavy hydrogen and tritium, so that the dangling bonds can be removed from interfaces between the isolation layer and the silicon substrate, and between the metal interconnection and the interlayer dielectric layer. Thus, interconnection characteristics can be improved.

In addition, according the image sensor of the embodiment, after the bonding pad is formed over the interlayer dielectric layer and the protective layer is formed over the interlayer dielectric layer including the bonding pad, the high pressure annealing process can be performed at least one time by using gas including at least one of hydrogen, heavy hydrogen and tritium, so that the dangling bonds can be removed from interfaces between the isolation layer and the silicon substrate, and between the metal interconnection and the interlayer dielectric layer. Thus, the interconnection characteristics can be improved.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing an image sensor, the method comprising:
forming a transistor structure over a semiconductor substrate; and
annealing the semiconductor substrate formed with the transistor structure at a high pressure.

2. The method of claim 1, further comprising forming an insulating layer over an entire surface of the semiconductor substrate formed with the transistor structure before the annealing is performed.

3. The method of claim 1, wherein the annealing is performed at a pressure of about 7 atm to about 40 atm by using gas including at least one of hydrogen, deuterium, tritium, nitrogen, argon and helium.

4. The method of claim 1, wherein the annealing is performed at a temperature of about 200° C. to about 600° C.

5. The method of claim 1, further comprising:
forming a metal interconnection over the semiconductor substrate formed with the transistor structure;
forming a protective layer over the metal interconnection layer; and
forming a color filter layer over the protective layer, after the annealing is performed.

6. A method for forming an image sensor, the method comprising:
forming a transistor structure over a semiconductor substrate;
forming a metal interconnection layer over the transistor structure; and
annealing the semiconductor substrate formed with the metal interconnection layer at a high pressure.

7. The method of claim 6, wherein the annealing is performed at a pressure of about 7 atm to about 40 atm by using gas including at least one of hydrogen, deuterium, tritium, nitrogen, argon and helium.

8. The method of claim 6, wherein the annealing is performed at a temperature of about 200° C. to about 600° C.

9. The method of claim 6, further comprising:
forming a protective layer over the metal interconnection layer; and
forming a color filter layer over the protective layer.

10. The method of claim 6, wherein the forming of the metal interconnection layer comprises:
forming an inter dielectric layer over the semiconductor substrate;
forming an etch stop layer over the interlayer dielectric layer; and
forming a metal layer over the etch stop layer.

11. The method of claim 6, wherein the metal interconnection layer includes a plurality of interlayer dielectric layers, an etch stop layer, and metal interconnections interposed between the interlayer dielectric layers, and
wherein the annealing is performed after forming at least one of the plural interlayer dielectric layers, the etch stop layer, and the metal interconnections.

12. A method of manufacturing an image sensor, the method comprising:
forming a gate pattern over a semiconductor substrate;
forming an insulating layer over the semiconductor substrate formed with the gate pattern;
forming a first metal interconnection and a capacitor electrode over the insulating layer;
forming a first interlayer dielectric layer over the insulating layer formed with the first metal interconnection and the capacitor electrode;
sequentially forming a first etch stop layer and a first metal layer over the first interlayer dielectric layer;
forming a second metal interconnection by patterning the first metal layer;
forming a second interlayer dielectric layer over the first interlayer dielectric layer formed with the second metal interconnection;
sequentially forming a second etch stop layer and a second metal layer over the second interlayer dielectric layer;
forming a third metal interconnection by patterning the second metal layer;
forming a third interlayer dielectric layer over the second interlayer dielectric layer formed with the third metal layer;
forming a protective layer over the third interlayer dielectric layer; and
forming a color filter layer over the protective layer,
wherein a high pressure annealing process is performed at least one time after the gate pattern is formed.

13. The method of claim 12, wherein the annealing process is performed at a pressure of about 7 atm to about 40 atm by using gas including at least one of hydrogen, deuterium, tritium, nitrogen, argon, and helium.

14. The method of claim 12, wherein the annealing is performed at a temperature of about 200° C. to about 600° C.

15. An image sensor comprising:
a transistor structure over a semiconductor substrate;
an insulating layer covering the transistor structure;
a metal interconnection layer over the insulating layer;
a protective layer over the metal interconnection layer; and
a color filter layer over the protective layer, wherein the semiconductor substrate including at least one of the transistor structure, the insulating layer, the metal interconnection layer, and the protective layer is subject to an annealing process under conditions of a pressure of about 7 atm to about 40 atm and a temperature of about 200° C. to about 600° C.

16. The image sensor of claim 15, wherein the annealing process is performed at a pressure of about 7 atm to about 40 atm by using gas including at least one of hydrogen, deuterium, tritium, nitrogen, argon, and helium.

17. The image sensor of claim 15, wherein the metal interconnection layer includes a plurality of interlayer dielectric layers, an etch stop layer, and metal interconnections interposed between the interlayer dielectric layers, and the annealing process is performed with respect to at least one of the interlayer dielectric layers, the etch stop layer, and the metal interconnections.
